(19) United States
(12) Patent Application Publication
(10) Pub. No.: US 2026/0239986 A1
(43) Pub. Date: Aug. 13, 2026

(54) STRUCTURE AND FORMATION METHOD OF PACKAGE WITH CRACK-STOPPING STRUCTURE

(71) Applicant: TAIWAN SEMICONDUCTOR MANUFACTURING COMPANY, LTD., Hsinchu (TW)

(72) Inventor: Shih-Yu LIAO, Taichung City (TW)

(73) Assignee: TAIWAN SEMICONDUCTOR MANUFACTURING COMPANY, LTD., Hsinchu (TW)

(21) Appl. No.: 19/052,821

(22) Filed: Feb. 13, 2025

(51) Int. Cl. H01L 23/00; H01L 23/58; H01L 25/07

(52) U.S. Cl. CPC H10W 42/121; H10W 42/00; H10W 90/00; H10W 72/019; H10W 72/01951; H10W 72/926; H10W 72/936; H10W 72/9445; H10W 72/963; H10W 72/967; H10W 80/312; H10W 80/327; H10W 90/26; H10W 90/792

(57) ABSTRACT

A package structure and a method for forming a package structure are provided. The method includes receiving a first chip-containing structure and partially removing the first chip-containing structure to form an opening extending into the first chip-containing structure. The method also includes forming a crack-stopping structure in the opening and forming a dielectric bonding structure over the first chip-containing structure and the crack-stopping structure. The method further includes forming multiple metal bonding structures extending into the first chip-containing structure, and top surfaces of the metal bonding structures and the dielectric bonding structure are level. In addition, the method includes bonding a second chip structure to the dielectric bonding structure and the metal bonding structures through dielectric-to-dielectric bonding and metal-to-metal bonding.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1K are cross-sectional views of various stages of a process for forming portion of a package structure, in accordance with some embodiments.

FIG. 2 is a top view of a portion of a package structure, in accordance with some embodiments.

FIG. 3 is a cross-sectional view of a portion of a package structure, in accordance with some embodiments.

FIG. 4 is a top view of a portion of a package structure, in accordance with some embodiments.

FIG. 5 is a top view of a portion of a package structure, in accordance with some embodiments.

FIG. 6 is a cross-sectional view of a portion of a package structure, in accordance with some embodiments.

FIG. 7 is a cross-sectional view of a portion of a package structure, in accordance with some embodiments.

FIG. 8 is a cross-sectional view of a portion of a package structure, in accordance with some embodiments.

FIG. 9 is a cross-sectional view of a portion of a package structure, in accordance with some embodiments.

FIG. 10 is a cross-sectional view of a portion of a package structure, in accordance with some embodiments.

FIG. 11 is a cross-sectional view of a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure and/or the package structure. Some of the features described below can be replaced or eliminated for different embodiments. Although some embodiments are discussed with operations performed in a particular order, these operations may be performed in another logical order.

Embodiments of the disclosure may relate to three-dimensional (3D) packaging or 3D-IC devices. Other features and processes may also be included. For example, testing structures may be included to aid in the verification testing of the 3D packaging or 3D-IC devices. The testing structures may include, for example, test pads formed in a redistribution layer or on a substrate that allows the testing of the 3D packaging or 3D-IC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

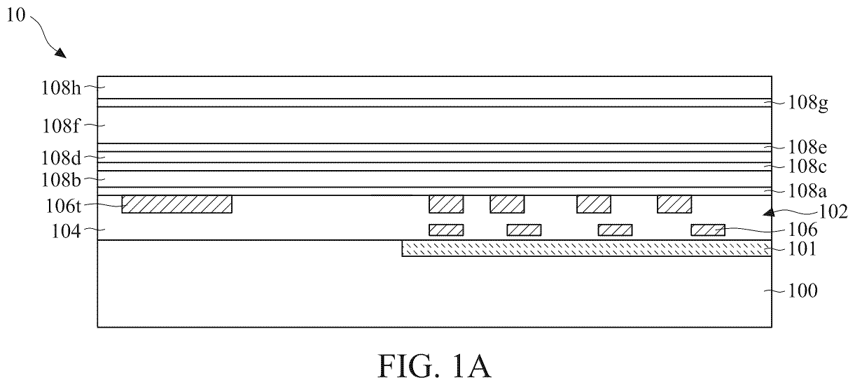

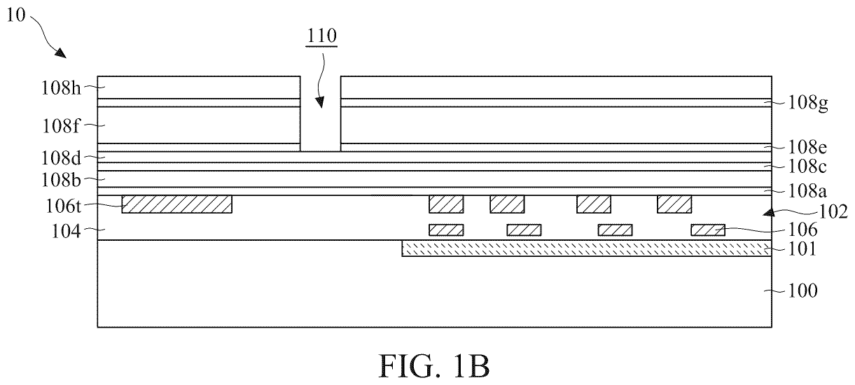

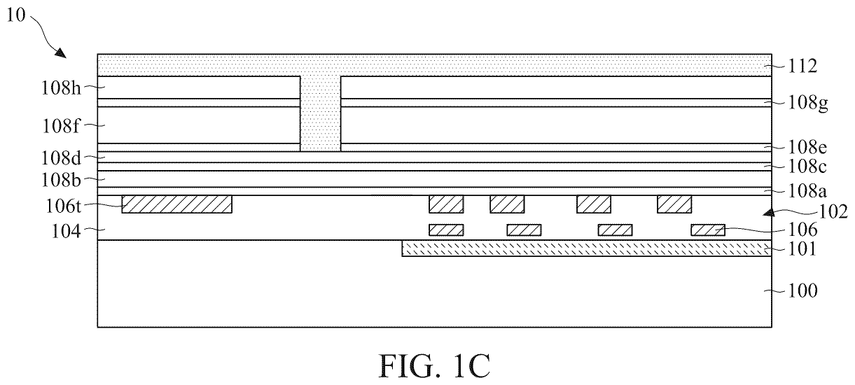

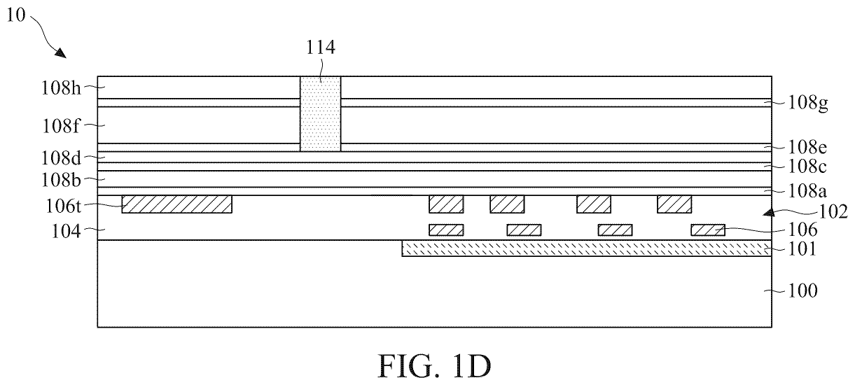

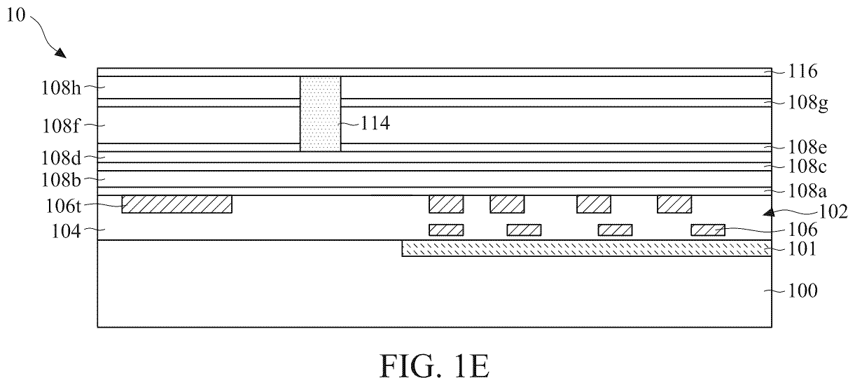

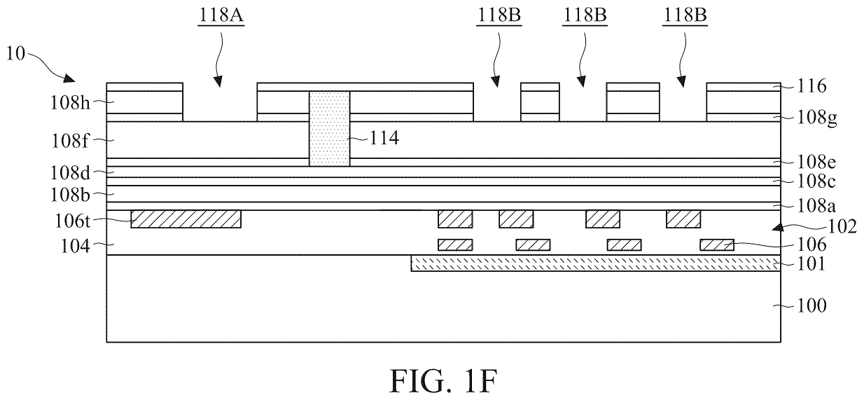

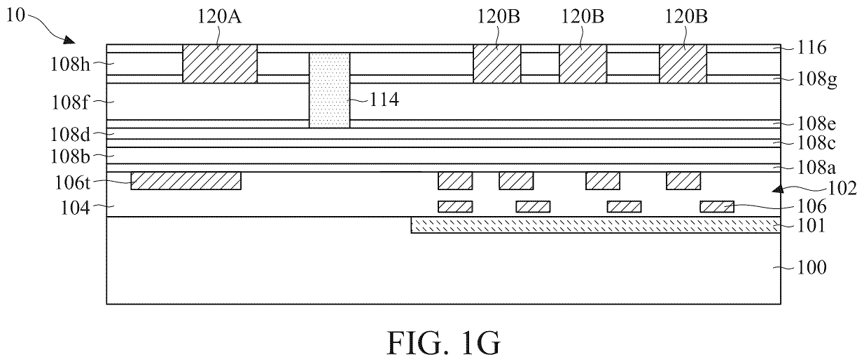

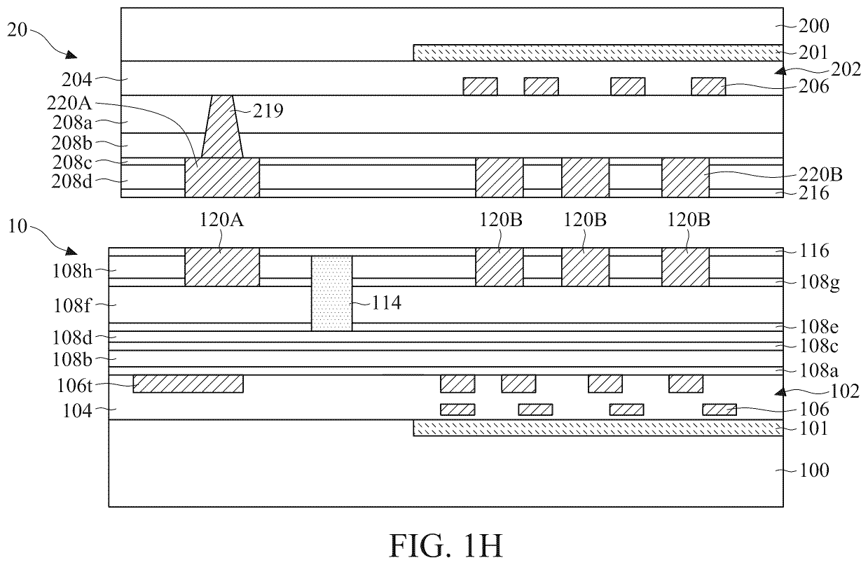

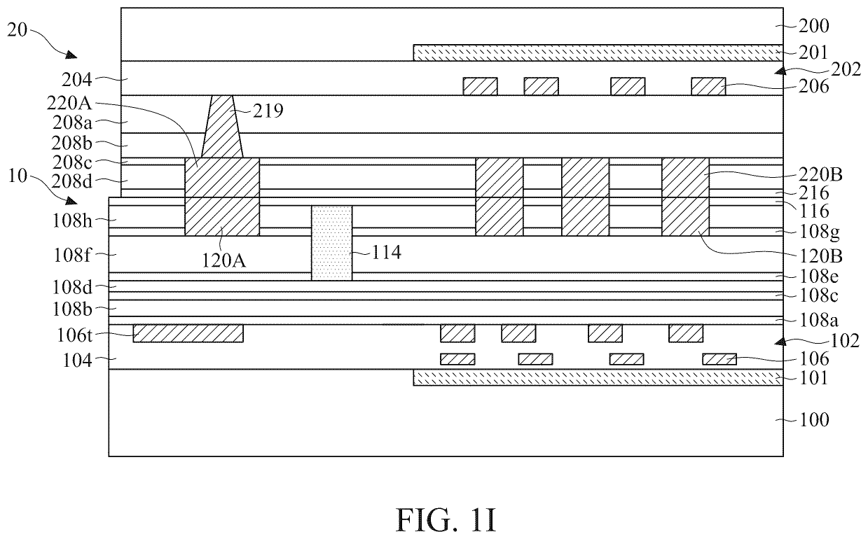

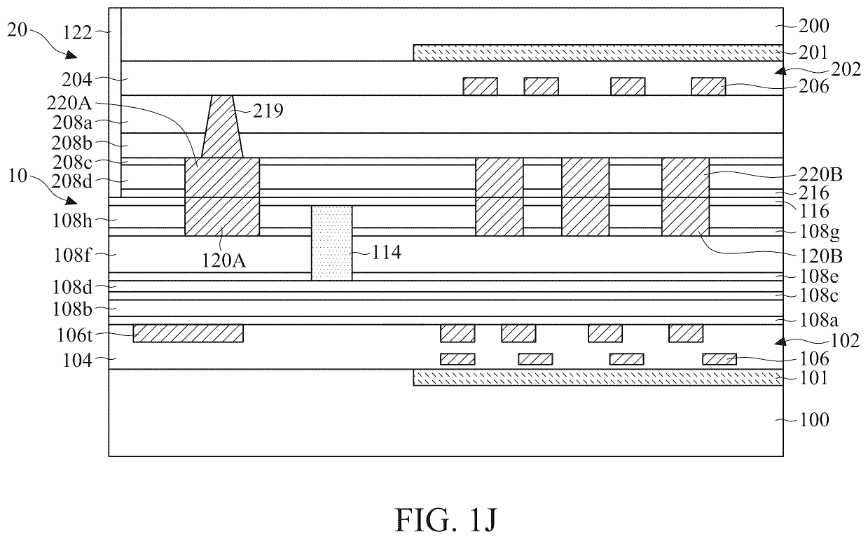

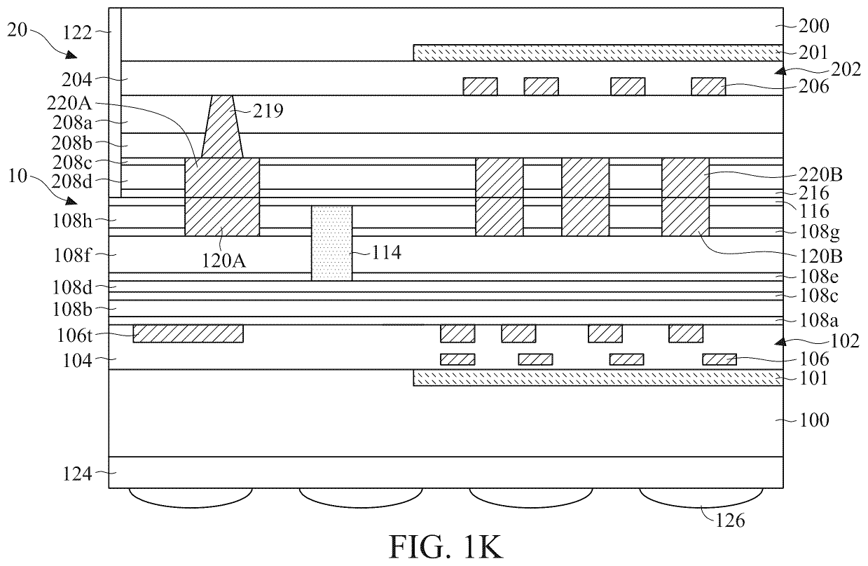

FIGS. 1A-1K are cross-sectional views of various stages of a process for forming portion of a package structure, in accordance with some embodiments. As shown in FIG. 1A, a chip-containing structure 10 is received, in accordance with some embodiments. In some embodiments, the chip-containing structure 10 is a semiconductor wafer that includes multiple semiconductor chips. After a subsequent sawing process, multiple semiconductor chips that are separated from each other may be obtained. In some other embodiments, the chip-containing structure 10 is a single semiconductor chip. In some other embodiments, the chip-containing structure 10 is a package containing one or more semiconductor chips.

In some embodiments, the chip-containing structure 10 includes a semiconductor substrate 100. The semiconductor substrate 100 may include silicon or another elementary semiconductor material such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

Various device elements 101 are formed in or over the semiconductor substrate 100. One of the device elements 101 is shown in FIG. 1A. Examples of the various device elements 101 include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or another suitable element. Various processes may be used to form the various device elements, including deposition, etching, implantation, photolithography, annealing, and other suitable processes.

The chip-containing structure 10 may include an interconnection structure 102 such as a front-side interconnection structure. In some embodiments, the interconnection structure 102 includes a dielectric portion 104 and multiple conductive features 106 surrounded by the dielectric portion 104. The conductive features 106 includes top conductive features 106t near the topmost surface of the dielectric portion 104. The top conductive features 106t may be thicker than the lower conductive features 106. The conductive features 106 may include conductive lines, conductive pads, conductive contacts, and conductive vias. The dielectric portion 104 includes multiple dielectric layers.

The dielectric layers of the dielectric portion 104 may be made of or include silicon oxide, silicon oxynitride, silicon nitride, carbon-containing silicon oxide, carbon-containing silicon nitride, carbon-containing silicon oxynitride, another suitable materials, or a combination thereof. The conductive features 106 may be made of or include copper, tungsten, cobalt, aluminum, tantalum, gold, another suitable material, or a combination thereof. The formation of the interconnection structure 102 may involve multiple deposition processes, patterning processes, planarization processes, another applicable process, or a combination thereof.

The device elements 101 of the chip-containing structure 10 are interconnected by the interconnection structure 102 to form integrated circuit devices, such as logic devices, memory devices (e.g., static random access memory, SRAM), radio frequency (RF) devices, input/output (I/O) devices, one or more other types of devices, or a combination thereof.

In some embodiments, multiple dielectric layers 108a-108g are formed over the interconnection structure 102, as shown in FIG. 1A. Each of the dielectric layers 108a-108g may be made of or include silicon oxide, silicon oxynitride, silicon nitride, carbon-containing silicon oxide, carbon-containing silicon nitride, carbon-containing silicon oxynitride, another suitable materials, or a combination thereof. The dielectric layers 108a-108g may assist in reducing the warpage of the chip-containing structure 10.

As shown in FIG. 1B, the dielectric layers 108d-108d of the chip-containing structure 10 are partially removed, in accordance with some embodiments. As a result, an opening 110 that extends into the chip-containing structure 10 is formed. One or more photolithography processes and one or more etching processes may be used to form the opening 110. The dielectric layer 108d may also function as an etch stop layer.

As shown in FIG. 1C, a crack-stopping material layer 112 is deposited over the chip-containing structure 10, in accordance with some embodiments. In some embodiments, the crack-stopping material layer 112 overfills the opening 110. The crack-stopping material layer 112 may cover the interfaces between the nearby layers of the dielectric layers 108e-108g. In some embodiments, the strength of the crack-stopping material layer 112 is greater than that of the dielectric layers 108e-108g.

In some embodiments, the crack-stopping material layer 112 is made of or includes an insulating material. The crack-stopping material layer 112 may be made of or include silicon nitride, silicon oxide, silicon carbide, carbon-containing silicon oxide, carbon-containing silicon nitride, carbon-containing silicon oxynitride. In some other embodiments, the crack-stopping material layer 112 is made of or includes an insulating material, a semiconductor material, a metal material, another suitable material, or a combination thereof.

The crack-stopping material layer 112 may be deposited using a chemical vapor deposition (CVD) process, an atomic layer deposition (ALD) process, a flowable chemical vapor deposition (FCVD) process, another applicable process, or a combination thereof.

As shown in FIG. 1D, the crack-stopping material layer 112 outside of the opening 110 is removed, in accordance with some embodiments. As a result, the remaining portion of the crack-stopping material layer 112 forms a crack-stopping structure 114. In some embodiments, a planarization process is used to partially remove the crack-stopping material layer 112. The planarization process may include a chemical mechanical polishing (CMP) process, a grinding process, an etching process, another applicable process, or a combination thereof. In some embodiments, the top surfaces of the crack-stopping structure 114 and the dielectric layer 108g are level. The width of the crack-stopping structure 114 may be in a range from about 1.5 μm to about 2.5 μm.

As shown in FIG. 1E, a dielectric bonding structure 116 is formed over the chip-containing structure 10 and the crack-stopping structure 114, in accordance with some embodiments. The dielectric bonding structure 116 may be made of or include silicon oxide, carbon-containing silicon oxide, silicon oxynitride, another suitable material, or a combination thereof. The dielectric bonding structure 116 may be deposited using a chemical vapor deposition (CVD) process or the like.

As shown in FIG. 1F, multiple openings 118A and 118B are formed, in accordance with some embodiments. The openings 118A and 118B penetrate through the dielectric bonding structure 116 and extend into the chip-containing structure 10. The opening 118A is near an outermost edge of the chip-containing structure 10 or a scribe line region of the chip-containing structure. The openings 118B are closer to the inner portion of the chip-containing structure 10 than the opening 118A. One or more photolithography processes and one or more etching processes may be used to form the openings 118A and 118B. The openings 118A and 118B may be used to contain metal bonding structures that will be formed later.

As shown in FIG. 1G, multiple metal bonding structures 120A and 120B are formed in the dielectric bonding structure 116, in accordance with some embodiments. In some embodiments, the metal bonding structure 120A is a portion of a seal ring structure that laterally surrounds the inner portion of the chip-containing structure 10. In some embodiments, the metal bonding structure 120A is laterally spaced apart from the crack-stopping structure 114 by a distance. The distance may be in a range from about 10 μm to about 50 μm. In some embodiments, the crack-stopping structure 114 is thicker than the metal bonding structure 120A. In some embodiments, the crack-stopping structure 114 span the bottom of the metal bonding structure 120A. The bottom of the metal bonding structure 120A is vertically between the top and bottom of the crack-stopping structure 114.

In some embodiments, some of the metal bonding structures 120B are electrically connected to the conductive features 106 thereunder. Multiple conductive lines and multiple conductive vias may be formed between the metal bonding structures 120B and the conductive features 106 of the interconnection structure 102.

The metal bonding structures 120A and 120B may be made of or include copper, cobalt, aluminum, gold, titanium, another suitable material, or a combination thereof. In some embodiments, one or more metal material layers are deposited to overfill the openings 118A and 118B. The metal material layers may be deposited using an electroplating process, an electrochemical plating process, a CVD process, another applicable process, or a combination thereof. Afterwards, a planarization process is used to remove the portions of the metal material layers that are outside of the openings 118A and 118B. As a result, the remaining portions of the metal material layers form the metal bonding structures 120a and 120b.

In some embodiments, the top surfaces of the dielectric bonding structure 116 and the metal bonding structures 120A and 120B are coplanar, as shown in FIG. 1G. In some embodiments, the formation of the metal bonding structures 120A and 120B involves one or more planarization processes, so as to ensure that top surfaces of the dielectric bonding structure 116 and the metal bonding structures 120A and 120B are highly planarized. For example, a chemical mechanical polishing (CMP) process is used. Therefore, the top surfaces of the dielectric bonding structure 116 and the metal bonding structures 120A and 120B are level.

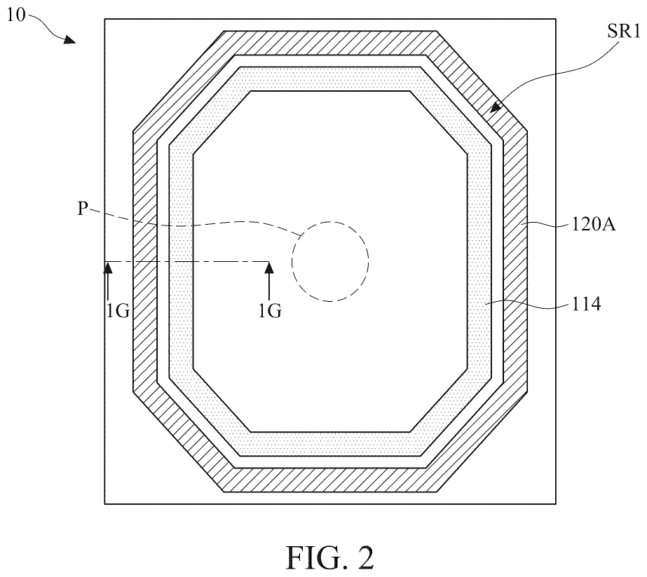

FIG. 2 is a top view of a portion of a package structure, in accordance with some embodiments. In some embodiments. FIG. 1G is a cross-sectional view of the structure taken along the line 1G-1G in FIG. 2. In FIG. 2, for clarity, the metal bonding structures 120B are not shown.

In some embodiments, the metal bonding structure 120A is a portion of a seal ring structure SR1. The seal ring structure SR1 laterally surrounds an inner portion P of the chip-containing structure 10, as shown in FIG. 2. In some embodiments, the crack-stopping structure 114 is also a ring structure that laterally surrounds the inner portion P. In some embodiments, the crack-stopping structure 114 continuously surrounds the inner portion P. In some embodiments, the seal ring structure SR1 continuously surrounds the crack-stopping structure 114 and the inner portion P of the chip-containing structure 10.

As shown in FIG. 1H, a chip-containing structure 20 is picked up and ready to be bonded to the chip-containing structure 10, in accordance with some embodiments. In some embodiments, the chip-containing structure 10 is wider than the chip-containing structure 20. In some embodiments, the chip-containing structure 20 is a single semiconductor chip. In some embodiments, the chip-containing structure 20 is a tested known good chip. In some other embodiments, the chip-containing structure 20 is a package containing one or more semiconductor chips.

In some embodiments, similar to the chip-containing structure 10, the chip-containing structure 20 includes a semiconductor substrate 200. In some embodiments, the semiconductor substrate 200 is a bulk semiconductor substrate. The semiconductor substrate 200 may include silicon or another elementary semiconductor material such as germanium. The semiconductor substrate 200 may be un-doped or doped (e.g., p-type, n-type, or a combination thereof). In some embodiments, the semiconductor substrate 200 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 200 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 200 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 200 includes a multi-layered structure. For example, the semiconductor substrate 200 includes a silicon-germanium layer formed on a bulk silicon layer.

Various device elements 201 are formed in or over the semiconductor substrate 200. One of the device elements 201 is shown in FIG. 1H. Examples of the various device elements 201 include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or another suitable element. Various processes may be used to form the various device elements, including deposition, etching, implantation, photolithography, annealing, and other suitable processes.

The chip-containing structure 20 may include an interconnection structure 202 such as a front-side interconnection structure. In some embodiments, the interconnection structure 202 includes a dielectric portion 204 and multiple conductive features 206 surrounded by the dielectric portion 204. The conductive features 206 may include conductive lines, conductive pads, conductive contacts, and conductive vias. The dielectric portion 204 includes multiple dielectric layers.

The dielectric layers of the dielectric portion 204 may be made of or include silicon oxide, silicon oxynitride, silicon nitride, carbon-containing silicon oxide, carbon-containing silicon nitride, carbon-containing silicon oxynitride, another suitable materials, or a combination thereof. The conductive features 206 may be made of or include copper, tungsten, cobalt, aluminum, tantalum, gold, another suitable material, or a combination thereof. The formation of the interconnection structure 202 may involve multiple deposition processes, patterning processes, planarization processes, another applicable process, or a combination thereof.

The device elements 201 of the chip-containing structure 20 are interconnected by the interconnection structure 202 to form integrated circuit devices, such as logic devices, memory devices (e.g., static random access memory, SRAM), radio frequency (RF) devices, input/output (I/O) devices, one or more other types of devices, or a combination thereof.

In some embodiments, multiple dielectric layers 208a-208d are formed over the interconnection structure 202, as shown in FIG. 1H. Each of the dielectric layers 208a-208d may be made of or include silicon oxide, silicon oxynitride, silicon nitride, carbon-containing silicon oxide, carbon-containing silicon nitride, carbon-containing silicon oxynitride, another suitable materials, or a combination thereof. The dielectric layers 208a-208d may assist in reducing the warpage of the chip-containing structure 20.

As shown in FIG. 1H, the chip-containing structure 20 also includes multiple metal bonding structures 220A and 220B and a dielectric bonding structure 216, in accordance with some embodiments. The dielectric bonding structure 216 laterally surrounds the metal bonding structures 220A and 220B. The dielectric bonding structure 216 may be made of or include silicon oxide, carbon-containing silicon oxide, silicon oxynitride, another suitable material, or a combination thereof. The dielectric bonding structure 216 may be deposited over the front-side interconnection structure using a chemical vapor deposition (CVD) process or the like.

In some embodiments, the dielectric bonding structures 216 and 116 have different compositions. In some embodiments, the dielectric bonding structures 216 and 116 have different atomic concentrations of nitrogen. For example, the dielectric bonding structure 116 may be made of silicon oxynitride, and the dielectric bonding structure 216 may be made of silicon oxide.

As shown in FIG. 1H, multiple metal bonding structures 220A and 220B are formed in the dielectric bonding structure 216, in accordance with some embodiments. The material and formation method of the metal bonding structures 220A and 220B may be the same as or similar to those of the metal bonding structures 120A and 120B. In some embodiments, a conductive via 219 is formed between the metal bonding structure 220A and the interconnection structure 202. In some embodiments, the metal bonding structure 220A and the conductive via 219 together form a portion of a seal ring structure that laterally surrounds the inner portion of the chip-containing structure 20.

In some embodiments, some of the metal bonding structures 220B are electrically connected to the conductive features 206 of the interconnection structure 202. Multiple conductive lines and multiple conductive vias may be formed between the metal bonding structures 220B and the conductive features 206 of the interconnection structure 202.

In some embodiments, the top surfaces of the dielectric bonding structure 216 and the metal bonding structures 220A and 220B are coplanar, as shown in FIG. 1H. In some embodiments. the formation of the metal bonding structures 220A and 220B involves one or more planarization processes, so as to ensure that top surfaces of the dielectric bonding structure 216 and the metal bonding structures 220A and 220B are highly planarized. For example, a chemical mechanical polishing (CMP) process is used. Therefore, the top surfaces of the dielectric bonding structure 216 and the metal bonding structures 220a and 220b are level.

As shown in FIG. 1I, the chip-containing structures 10 and 20 are bonded together through direct bonding, in accordance with some embodiments. The direct bonding may include dielectric-to-dielectric bonding and metal-to-metal bonding. In some embodiments, there is no tin-containing solder elements or solder bump formed between the chip-containing structures 10 and 20. In some embodiments, the bonding between the chip-containing structures 10 and 20 is a bumpless thermos-compression bonding.

In some embodiments, the chip-containing structure 20 is picked and placed directly on the dielectric bonding structure 116 and the metal bonding structures 120A and 120B. As a result, the dielectric bonding structure 116 of the chip-containing structure 10 is in direct contact with the dielectric bonding structure 216 of the chip-containing structure 20. The metal bonding structures 120A and 120B of the chip-containing structure 10 are in direct contact with the metal bonding structures 220A and 220B of the chip-Containing structure 20.

Before the placing of the chip-containing structure 20, planarization processes are performed, so as to provide highly planarized bonding surfaces. In some embodiments, there is no gap between the dielectric bonding structure 116 and the dielectric bonding structure 216. In some embodiments, there is no gap between the metal bonding structures 120A and 120B and the metal bonding structures 220A and 220B. In some embodiments, a thermal operation is then used to enhance the bonding between the metal bonding structures 120A and 120B and the metal bonding structures 220A and 220B. The temperature of the thermal operation may within a range from about 100 degrees C. to about 500 degrees C. In some embodiments, a thermos-compression process is used to enhance the bonding between the chip-containing structures 10 and 20.

In some cases, the edge portions of the chip-containing structures 10 and 20 may not bond properly, leading to slight delamination. For instance, delamination may occur at the interface between the dielectric layers 108g and 108f near the edges of the chip-containing structures 10 and 20. This delamination may propagate inward from the edges, potentially resulting in crack formation that adversely impacts the performance and reliability of the package structure.

In some embodiments, the crack-stopping structure 114, which spans the interface between dielectric layers 108g and 108f, prevents or blocks the propagation of delamination. This ensures proper bonding between the inner portions of the chip-containing structures 10 and 20, thereby enhancing the performance and reliability of the package structure.

As shown in FIG. 1J, a protective layer 122 is formed over the chip-containing structure 10 to laterally surround the chip-containing structure 20, in accordance with some embodiments. The protective layer 122 may be made of or include silicon oxide, silicon oxynitride, silicon nitride, carbon-containing silicon oxide, carbon-containing silicon oxynitride, carbon-containing silicon nitride, another suitable material, or a combination thereof. In some other embodiments, the protective layer 122 is made of a molding compound material or an epoxy-based resin material.

In some embodiments, an insulating material layer used for forming the protective layer 122 is deposited over the chip-containing structures 10 and 20. The insulating material layer may be deposited using a CVD process, an atomic layer deposition (ALD) process, a flowable chemical vapor deposition (FCVD) process, a spin-coating process, another applicable process, or a combination thereof. Afterwards, a planarization process is used to partially remove the insulating material layer. As a result, the remaining portion of the insulating material layer forms the protective layer 122. The planarization process may include a CMP process, a grinding process, an etching process, a dry polishing process, another applicable process, or a combination thereof.

As shown in FIG. 1K, a redistribution structure 124 and multiple conductive bumps 126 are formed, in accordance with some embodiments. The redistribution structure 124 may include multiple insulating layers and multiple conductive features for routing. In some embodiments, the redistribution structure 124 and the conductive bumps 126 are formed below the chip-containing structure 10. In some other embodiments, the redistribution structure 124 and the conductive bumps 126 are formed above the protective layer 122 and the chip-containing structure 20.

Afterwards, in some embodiments, a sawing process is used to separate the structure into multiple package structures. One of the package structures is shown in FIG. 1K. In some embodiments, the chip-containing structure 10 is originally a semiconductor wafer. After the sawing process, the chip-containing structure 10 shown in FIG. 1K may be a single semiconductor chip. In some embodiments, the outermost edge of the protective layer 122 is coplanar with the outermost edge of the chip-containing structure 10. The package structure shown in FIG. 1K may function as a system on integrated chips (SoIC) that may further be integrated into another package structure.

Many variations and/or modifications can be made to embodiments of the disclosure. In some embodiments, each of the chip-containing structures 10 and 20 has a seal ring structure formed therein.

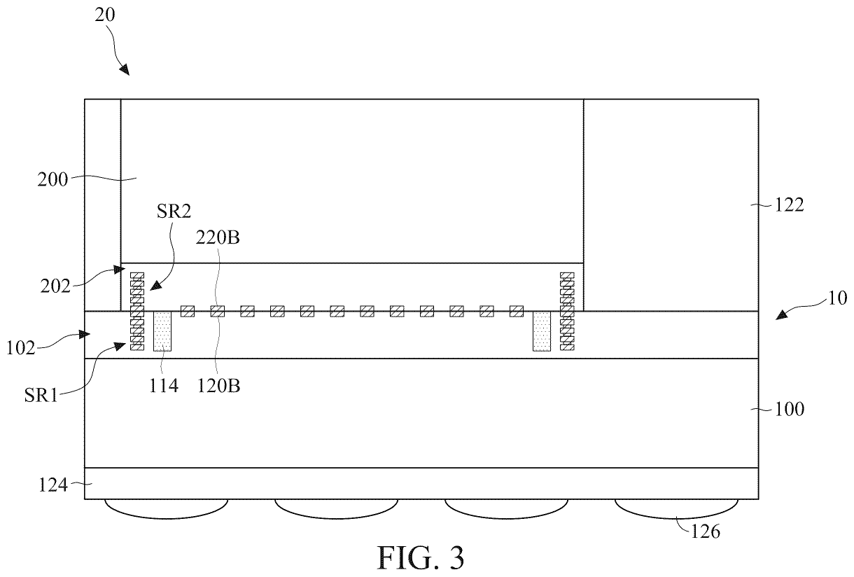

FIG. 3 is a cross-sectional view of a portion of a package structure, in accordance with some embodiments. In some embodiments, a package structure that is similar to the structure shown in FIGS. 1K and 2 is formed. In some embodiments, the seal ring structure SR1 that includes multiple conductive lines and conductive vias is formed in the interconnection structure 102 of the chip-containing structure 10. In some embodiments, similar to the chip-containing structure 10, a seal ring structure SR2 is formed in the interconnection structure 202 of the chip-containing structure 20.

In some embodiments, the seal ring structures SR1 and SR2 are aligned with each other. In some embodiments, the seal ring structure SR2 covers a portion of the seal ring structure SR1. In some embodiments, the seal ring structure SR1 laterally and continuously surrounds the crack-stopping structure 114, similar to that shown in FIG. 2.

Even if the edge portions of the chip-containing structures 10 and 20 might not bond properly, the crack-stopping structure 114 may help to prevent or block the propagation of delamination. This ensures proper bonding between the inner portions of the chip-containing structures 10 and 20, thereby enhancing the performance and reliability of the package structure.

In some embodiments, the crack-stopping structure 114 is a ring structure that laterally surrounds the inner portion of the chip-containing structure 10. However, embodiments of the disclosure are not limited thereto. Many variations and/or modifications can be made to embodiments of the disclosure. In some other embodiments, the crack-stopping structure 114 is not a ring structure.

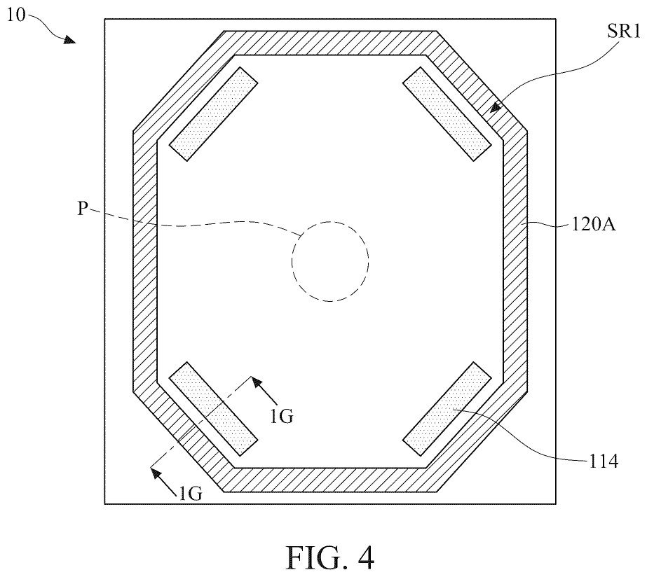

FIG. 4 is a top view of a portion of a package structure, in accordance with some embodiments. A structure that is similar to that shown in FIG. 2 is formed. In some embodiments, the crack-stopping structure 114 has a stripe-like profile. In some embodiments, the crack-stopping structure 114 is positioned near a corner portion of the chip-containing structure 10. In some embodiments, multiple crack-stopping structures 114 are formed. The crack-stopping structures 114 may be positioned at the corner portions of the chip-containing structure 10 to prevent or block the propagation of delamination from the corners of the chip-containing structure 10.

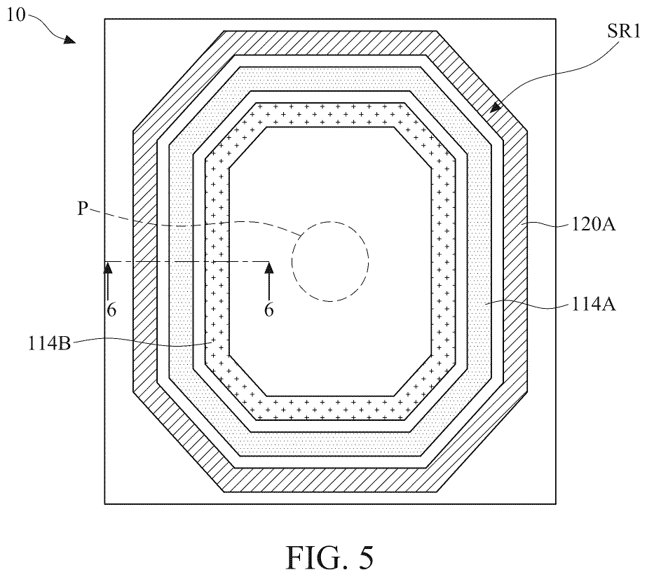

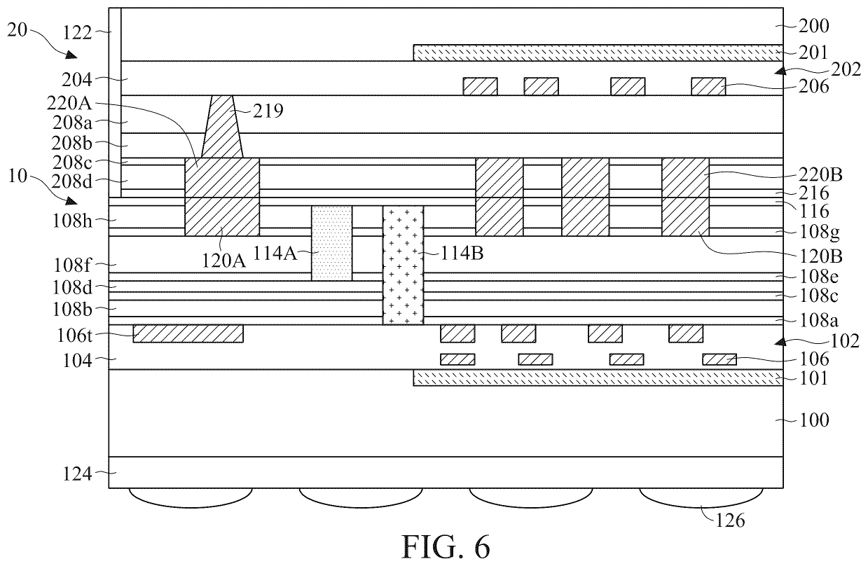

Many variations and/or modifications can be made to embodiments of the disclosure. FIG. 5 is a top view of a portion of a package structure, in accordance with some embodiments. FIG. 6 is a cross-sectional view of a portion of a package structure, in accordance with some embodiments. In some embodiments, FIG. 6 is a cross-sectional view of the structure taken along the line 6 -6 in FIG. 5. A structure that is similar to that shown in FIGS. 1K and 2 is formed.

In some embodiments, multiple crack-stopping structures 114A and 114B are formed to laterally surround the inner portion P of the chip-containing structure 10, as shown in FIGS. 5 and 6. In some embodiments, the crack-stopping structures 114A and 114B are ring structures. In some embodiments, the crack-stopping structure 114B laterally surrounds the inner portion P. In some embodiments, the crack-stopping structure 114A laterally surrounds the crack-stopping structure 114B and the inner portion P. In some embodiments, the seal ring structure SR1 laterally surrounds the crack-stopping structures 114A and 114B and the inner portion P.

In some embodiments, the crack-stopping structure 114B extends deeper into the chip-containing structure 10 than the crack-stopping structure 114A. The crack-stopping structure 114B is closer to the semiconductor substrate 100 than the crack-stopping structure 114A. The crack-stopping structures 114A and 114B may work together to prevent and block delamination propagation from the edge portions of the package structure, which significantly reduce the crack issue. The performance and reliability of the package structure are greatly improved.

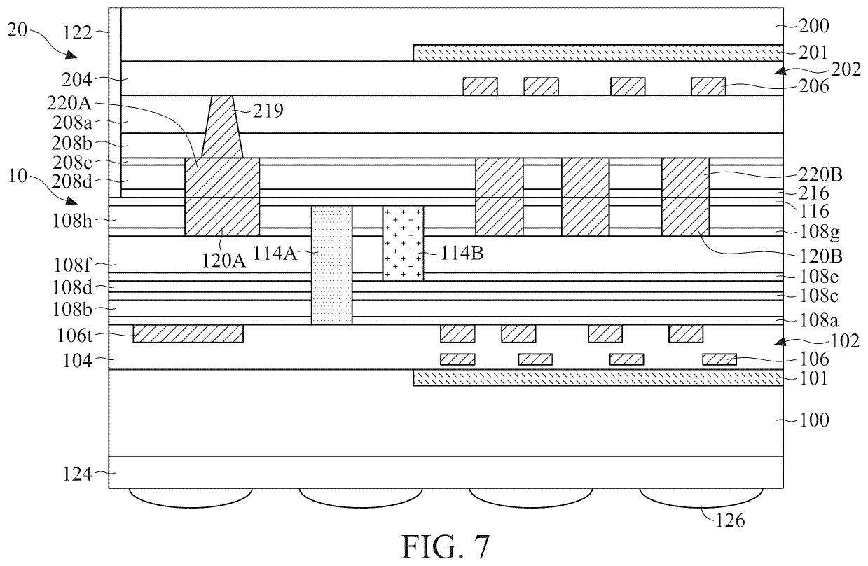

Many variations and/or modifications can be made to embodiments of the disclosure. FIG. 7 is a cross-sectional view of a portion of a package structure, in accordance with some embodiments. A structure that is similar to that shown in FIGS. 5 and 6 is formed. In some embodiments, the crack-stopping structure 114A extends deeper into the chip-containing structure 10 than the crack-stopping structure 114B. The crack-stopping structure 114A is closer to the semiconductor substrate 100 than the crack-stopping structure 114B. The crack-stopping structures 114A and 114B may work together to prevent and block delamination propagation from the edge portions of the package structure. The performance and reliability of the package structure are greatly improved.

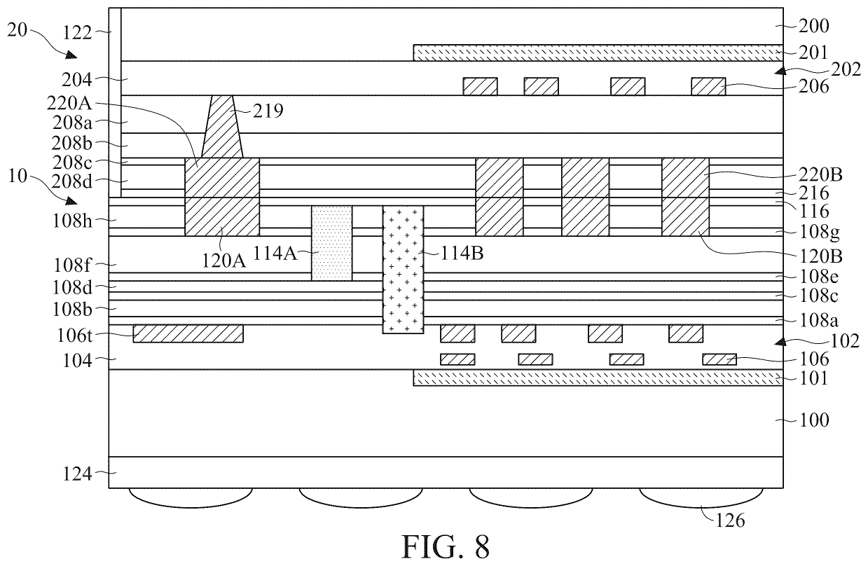

Many variations and/or modifications can be made to embodiments of the disclosure. FIG. 8 is a cross-sectional view of a portion of a package structure, in accordance with some embodiments. A structure that is similar to that shown in FIGS. 5 and 6 is formed. In some embodiments, the crack-stopping structure 114B further extends into the interconnection structure 102. In some embodiments, the bottom of the crack-stopping structure 114B is vertically between the top and bottom of the top conductive feature 106t. The crack-stopping structures 114A and 114B may work together to prevent and block delamination propagation from the edge portions of the package structure. The performance and reliability of the package structure are greatly improved.

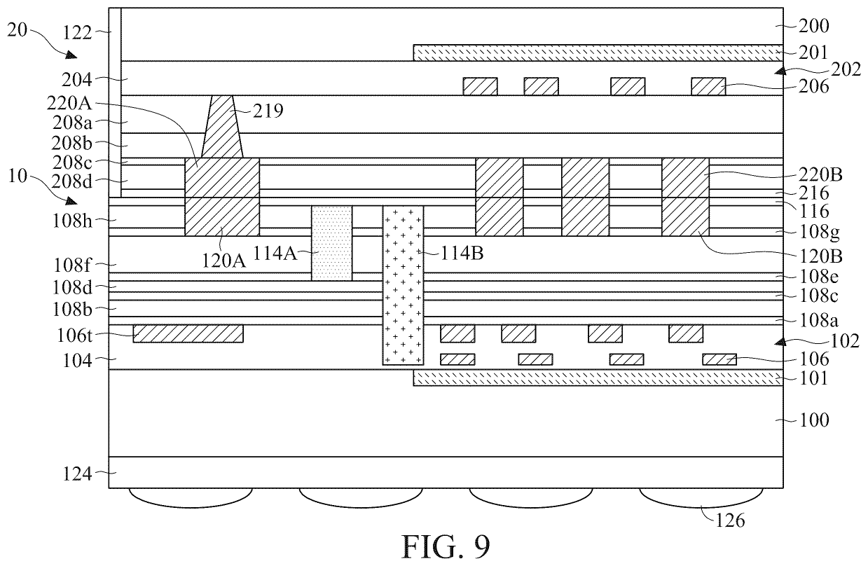

Many variations and/or modifications can be made to embodiments of the disclosure. FIG. 9 is a cross-sectional view of a portion of a package structure, in accordance with some embodiments. A structure that is similar to that shown in FIGS. 5 and 6 is formed. In some embodiments, the crack-stopping structure 114B further extends into the interconnection structure 102. In some embodiments, the bottom of the crack-stopping structure 114B is vertically between the bottom of the top conductive feature 106t and the semiconductor substrate 100. The crack-stopping structures 114A and 114B may work together to prevent and block delamination propagation from the edge portions of the package structure. The performance and reliability of the package structure are greatly improved.

In some embodiments, the crack-stopping structure is formed in one of the chip-containing structures that are bonded together. However, embodiments of the disclosure are not limited thereto. Many variations and/or modifications can be made to embodiments of the disclosure. In some embodiments, similar to the chip-containing structure 10, one or more crack-stopping structures are also formed in the chip-containing structure 20.

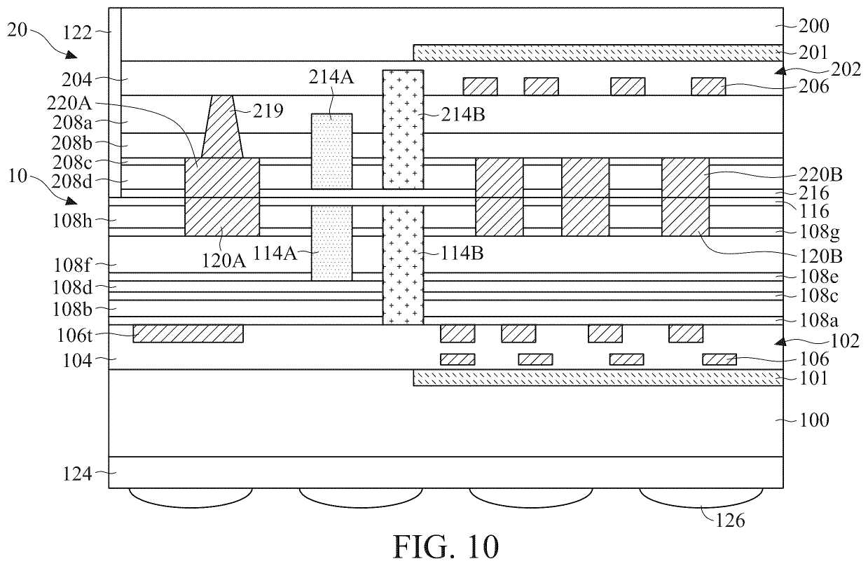

FIG. 10 is a cross-sectional view of a portion of a package structure, in accordance with some embodiments. A structure that is similar to that shown in FIGS. 5 and 6 is formed. In some embodiments, crack-stopping structures 214A and 214B are formed in the chip-containing structure 20. The material and formation method of the crack-stopping structures 214A and 214B may be the same as or similar to those of the crack-stopping structure 114. In some embodiments, the crack-stopping structures 214A and 214B cover portions of the crack-stopping structures 114A and 114B. In some embodiments, the crack-stopping structures 214A and 214B are aligned with the crack-stopping structures 114A and 114B. The crack-stopping structures 114A, 114B, 214A and 214B may work together to prevent and block delamination propagation from the edge portions of the package structure. The performance and reliability of the package structure are greatly improved.

In some embodiments, the crack-stopping structure is formed between the inner portion of the chip-containing structure and a portion of the seal ring structure. However, embodiments of the disclosure are not limited thereto. Many variations and/or modifications can be made to embodiments of the disclosure. In some other embodiments, one or more crack-stopping structures are formed between the edge of the chip-containing structure and a portion of the seal ring structure.

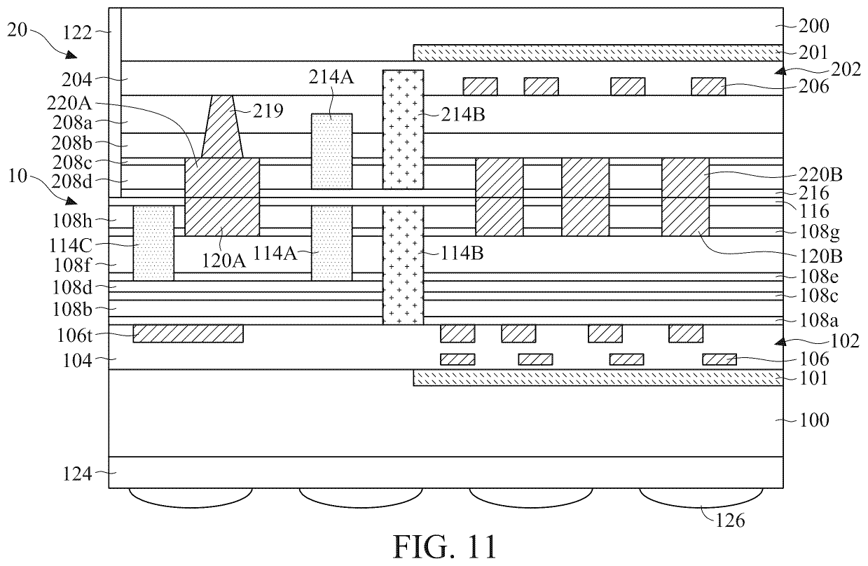

FIG. 11 is a cross-sectional view of a portion of a package structure, in accordance with some embodiments. In some embodiments, a crack-stopping structure 114C is formed between the edge of the chip-containing structure 10 and the metal bonding structure 120A. In some embodiments, the metal bonding structure 120A functions as a seal ring structure. In some embodiments, the metal bonding structure 120A is a portion of a seal ring structure that laterally surrounds the inner portion of the chip-containing structure 10.

Embodiments of the disclosure form a package structure with multiple bonded chip-containing structures. A crack-stopping structure is formed near the edge of the package structure. Even if delamination occurs at the edge portions of the bonded chip-containing structures, the crack-stopping structure may help to prevent or block the propagation of delamination. The potential risk of crack is reduced or prevented. This ensures proper bonding between the inner portions of the bonded chip-containing structures, thereby enhancing the performance and reliability of the package structure.

In accordance with some embodiments, a method for forming a package structure is provided. The method includes receiving a first chip-containing structure and partially removing the first chip-containing structure to form an opening extending into the first chip-containing structure. The method also includes forming a crack-stopping structure in the opening and forming a dielectric bonding structure over the first chip-containing structure and the crack-stopping structure. The method further includes forming multiple metal bonding structures extending into the first chip-containing structure, and top surfaces of the metal bonding structures and the dielectric bonding structure are level. In addition, the method includes bonding a second chip structure to the dielectric bonding structure and the metal bonding structures through dielectric-to-dielectric bonding and metal-to-metal bonding.

In accordance with some embodiments, a method for forming a package structure is provided. The method includes receiving a first chip-containing structure and forming a crack-stopping structure extending into the first chip-containing structure. The crack-stopping structure laterally surrounds an inner portion of the first chip-containing structure. The method also includes forming a dielectric bonding structure over the first chip-containing structure and forming multiple metal bonding structures extending into the first chip-containing structure. Top surfaces of the metal bonding structures and the dielectric bonding structure are level. The method further includes bonding a second chip structure to the dielectric bonding structure and the metal bonding structures through dielectric-to-dielectric bonding and metal-to-metal bonding.

In accordance with some embodiments, a package structure is provided. The package structure includes a first chip-containing structure and a dielectric bonding structure over the first chip-containing structure. The package structure also includes multiple metal bonding structures laterally surrounded by the dielectric bonding structure, and top surfaces of the metal bonding structures and the dielectric bonding structure are level. The package structure further includes a second chip-containing structure bonded to the dielectric bonding structure and the metal bonding structures through dielectric-to-dielectric bonding and metal-to-metal bonding. In addition, the package structure includes a crack-stopping structure extending into the first chip-containing structure. The crack-stopping structure is between an inner portion of the first chip-containing structure and an outer metal bonding structure of the metal bonding structures. The outer metal bonding structure is between an edge of the first chip-containing structure and the outer metal bonding structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package structure, comprising:
receiving a first chip-containing structure;
partially removing the first chip-containing structure to form an opening extending into the first chip-containing structure;
forming a crack-stopping structure in the opening;
forming a dielectric bonding structure over the first chip-containing structure and the crack-stopping structure;
forming a plurality of metal bonding structures extending into the first chip-containing structure, wherein top surfaces of the metal bonding structures and the dielectric bonding structure are level; and
bonding a second chip structure to the dielectric bonding structure and the metal bonding structures through dielectric-to-dielectric bonding and metal-to-metal bonding.

2. The method for forming a package structure as claimed in claim 1, further comprising:
forming a seal ring structure in the first chip-containing structure, wherein the seal ring structure laterally surrounds an inner portion of the first chip-containing structure and an upper portion of the crack-stopping structure.

3. The method for forming a package structure as claimed in claim 2, wherein the crack-stopping structure laterally surrounds the inner portion of the first chip-containing structure.

4. The method for forming a package structure as claimed in claim 3, further comprising:
forming a second crack-stopping structure extending into the first chip-containing structure, wherein the crack-stopping structure is between the second crack-stopping structure and the seal ring structure.

5. The method for forming a package structure as claimed in claim 4, wherein the second crack-stopping structure extends deeper into the first chip-containing structure than the crack-stopping structure.

6. The method for forming a package structure as claimed in claim 4, wherein the crack-stopping structure extends deeper into the first chip-containing structure than the second crack-stopping structure.

7. The method for forming a package structure as claimed in claim 4, wherein the second crack-stopping structure laterally surrounds the inner portion of the first chip-containing structure.

8. The method for forming a package structure as claimed in claim 1, further comprising:
forming a second seal ring structure in the second chip-containing structure before the bonding of the second chip structure to the dielectric bonding structure and the metal bonding structures, wherein the second seal ring structure covers at least a portion of the seal ring structure.

9. The method for forming a package structure as claimed in claim 8, further comprising:
forming an upper crack-stopping structure in the second chip-containing structure before the bonding of the second chip structure to the dielectric bonding structure and the metal bonding structures, wherein a portion of the second seal ring structure is between the upper crack-stopping structure and an edge of the second chip-containing structure.

10. The method for forming a package structure as claimed in claim 1, further comprising:
forming an insulating layer overfilling the opening; and
partially removing the insulating layer by planarizing the insulating layer, wherein a remaining portion of the insulating layer forms the crack-stopping structure.

11. A method for forming a package structure, comprising:
receiving a first chip-containing structure;
forming a crack-stopping structure extending into the first chip-containing structure, wherein the crack-stopping structure laterally surrounds an inner portion of the first chip-containing structure;
forming a dielectric bonding structure over the first chip-containing structure;
forming a plurality of metal bonding structures extending into the first chip-containing structure, wherein top surfaces of the metal bonding structures and the dielectric bonding structure are level; and
bonding a second chip structure to the dielectric bonding structure and the metal bonding structures through dielectric-to-dielectric bonding and metal-to-metal bonding.

12. The method for forming a package structure as claimed in claim 11, wherein the crack-stopping structure is made of an insulating material.

13. The method for forming a package structure as claimed in claim 11, further comprising:
forming a seal ring structure in the first chip-containing structure, wherein the seal ring structure laterally surrounds the crack-stopping structure.

14. The method for forming a package structure as claimed in claim 13, further comprising:
forming a second crack-stopping structure laterally surrounding the crack-stopping structure, wherein the seal ring structure laterally surrounds the second crack-stopping structure.

15. The method for forming a package structure as claimed in claim 11, further comprising:
forming a second crack-stopping structure extending into the first chip-containing structure, wherein the second crack-stopping structure is between the crack-stopping structure and an edge of the first chip-containing structure.

16. A package structure, comprising:
a first chip-containing structure;
a dielectric bonding structure over the first chip-containing structure;
a plurality of metal bonding structures laterally surrounded by the dielectric bonding structure, wherein top surfaces of the metal bonding structures and the dielectric bonding structure are level;
a second chip-containing structure bonded to the dielectric bonding structure and the metal bonding structures through dielectric-to-dielectric bonding and metal-to-metal bonding; and
a crack-stopping structure extending into the first chip-containing structure, wherein the crack-stopping structure is between an inner portion of the first chip-containing structure and an outer metal bonding structure of the metal bonding structures, and the outer metal bonding structure is between an edge of the first chip-containing structure and the outer metal bonding structure.

17. The package structure as claimed in claim 16, wherein the outer metal bonding structure is a portion of a seal ring structure laterally surrounding an inner portion of the first chip-containing structure.

18. The package structure as claimed in claim 17, further comprising:
a second crack-stopping structure extending into the second chip-containing structure, wherein the second crack-stopping structure covers a portion of the crack-stopping structure.

19. The package structure as claimed in claim 18, further comprising:
a second seal ring structure extending into the second chip-containing structure, wherein a portion of the second seal ring structure is between the second crack-stopping structure and an edge of the second chip-containing structure, and the second seal ring structure covers a portion of the seal ring structure.

20. The package structure as claimed in claim 16, further comprising:
an inner crack-stopping structure extending into the first chip-containing structure, wherein the inner crack-stopping structure is between the crack-stopping structure and the inner portion of the first chip-containing structure.
